(19) United States
(12) Patent Application Publication
(10) Pub. No.: US 2025/0300056 A1
(43) Pub. Date: Sep. 25, 2025

(54) INTEGRATED DEVICE WITH CONDUCTIVE PILLAR STRUCTURE FOR DIE INTERCONNECTION

(71) Applicant: QUALCOMM Incorporated, San Diego, CA (US)

(72) Inventors: Hong Bok WE, San Diego, CA (US); Joan Rey Villarba BUOT, Escondido, CA (US); Kuiwon KANG, San Diego, CA (US); Omar James BCHIR, San Marcos, CA (US)

(21) Appl. No.: 18/609,991

(22) Filed: Mar. 19, 2024

(51) Int. Cl. H01L 23/498; H01L 21/48; H01L 23/00; H01L 25/065

(52) U.S. Cl. CPC H01L 23/49838; H01L 21/4846; H01L 24/13; H01L 24/14; H01L 24/16; H01L 24/81; H01L 25/0655; H01L 2224/13082; H01L 2224/1403; H01L 2224/16237; H01L 2224/16238; H01L 2224/81815

(57) ABSTRACT

A device includes a substrate that includes a set of metal layers, separated from one another by a set of dielectric layers. The set of metal layers define a first set of metal lines and a second set of metal lines. The substrate includes a first set of conductive pillars configured to be electrically connected to a first die, and a second set of conductive pillars interconnecting the first set of metal lines to the first set of conductive pillars. The substrate also includes a first set of pads configured to be electrically connected to the first die, and a first set of conductive vias interconnecting the second set of metal lines to the first set of pads. The first set of conductive pillars extend from a surface of the substrate.

### FIELD

Various features relate to integrated devices.

### BACKGROUND

Electrical connections exist at each level of a system hierarchy. This system hierarchy includes interconnection of active devices at a lowest system level all the way up to system level interconnections at the highest level. For example, interconnect layers can connect different devices together on an integrated circuit. As integrated circuits become more complex, more interconnect layers are used to provide the electrical connections between the devices. More recently, the number of interconnect levels for circuitry has substantially increased due to the large number of devices that are now interconnected in a modern electronic device. The increased number of interconnect levels for supporting the increased number of devices involves more intricate processes.

State-of-the-art mobile application devices demand a small form factor, low cost, a tight power budget, and high electrical performance. Mobile package design has evolved to meet these divergent goals for enabling mobile applications that support multimedia enhancements. These mobile applications, however, are susceptible to power and signal routing issues when multiple dies are arranged within the small form factor. Design and manufacture of devices for use in mobile applications is challenging due to conflicts among the various design goals. For example, smaller form factor devices are generally more expensive to design and manufacture and small size can exacerbate other issues, such as heat management. As another example, performance can be increased by providing more signal paths between dies; however, providing more signal paths generally increases cost and size.

### SUMMARY

Various features relate to integrated devices.

One example provides a device that includes a substrate. The substrate includes a set of metal layers, separated from one another by a set of dielectric layers, the set of metal layers defining a first set of metal lines and a second set of metal lines. The substrate includes a first set of conductive pillars configured to be electrically connected to a first die. The substrate includes a second set of conductive pillars interconnecting the first set of metal lines to the first set of conductive pillars. The substrate includes a first set of pads configured to be electrically connected to the first die. The substrate also includes a first set of conductive vias interconnecting the second set of metal lines to the first set of pads. The first set of conductive pillars extend from a surface of the substrate.

Another example provides a device that includes a first die including first circuitry and a second die including second circuitry. The device also includes a substrate configured to electrically connect the first circuitry to the second circuitry and to electrically connect the first circuitry, the second circuitry, or both, to one or more off-package devices. The substrate includes a set of metal layers, separated from one another by a set of dielectric layers. The set of metal layers define a first set of metal lines and a second set of metal lines. The substrate includes a first set of conductive pillars electrically connected to the first die. The substrate includes a first set of pads electrically connected to the first die. The substrate includes a second set of conductive pillars interconnecting the first set of metal lines to the first set of conductive pillars. The substrate includes a first set of conductive vias interconnecting the second set of metal lines to the first set of pads. The substrate includes a third set of conductive pillars electrically connected to the second die. The substrate includes a second set of pads electrically connected to the second die. The substrate includes a fourth set of conductive pillars interconnecting the first set of metal lines to the third set of conductive pillars to interconnect the first die to the second die. The substrate also includes a second set of conductive vias interconnecting the second set of metal lines to the second set of pads. The first set of conductive pillars and the third set of conductive pillars extend from a surface of the substrate.

Another example provides a method of fabrication of a device. The method includes forming, in a metal layer of a substrate, first metal lines of a first set of metal lines and second metal lines of a second set of metal lines. The method includes forming, in a dielectric layer above the metal layer, second conductive pillars connected to the first metal lines. The method includes forming, in the dielectric layer, conductive vias connected to the second metal lines. The method includes forming pads connected to the conductive vias and configured to be electrically connected to a first die. The method also includes forming first conductive pillars connected to the second conductive pillars and configured to be electrically connected to a first die. The first conductive pillars extend from a surface of the substrate.

### BRIEF DESCRIPTION OF THE DRAWINGS

Various features, nature and advantages may become apparent from the detailed description set forth below when taken in conjunction with the drawings in which like reference characters identify correspondingly throughout.

FIG. 1 illustrates a cross-sectional profile view of a device that includes a conductive pillar structure for die interconnection.

FIG. 2 illustrates cross-sectional profile views of pillars, pads, vias, and lines that may be included in the device of FIG. 1.

FIGS. 3A, 3B, 3C, and 3D together illustrate an exemplary sequence for fabricating a device that includes a conductive pillar structure for die interconnection.

FIGS. 4A, 4B, and 4C together illustrate stages of another exemplary sequence for fabricating a device that includes a conductive pillar structure for die interconnection.

FIG. 5 is a flowchart illustrating an exemplary method for fabricating a device that includes a conductive pillar structure for die interconnection.

FIG. 6 illustrates various electronic devices that may integrate a die, an electronic circuit, an integrated device, an integrated passive device (IPD), a passive component, a package, and/or a device package described herein.

### DETAILED DESCRIPTION

In the following description, specific details are given to provide a thorough understanding of the various aspects of the disclosure. However, it will be understood by one of ordinary skill in the art that the aspects may be practiced without these specific details. For example, circuits may be shown in block diagrams in order to avoid obscuring the aspects in unnecessary detail. In other instances, well-known circuits, structures and techniques may not be shown in detail in order not to obscure the aspects of the disclosure. As another example, various devices and structures disclosed herein are illustrated schematically. Such schematic representations are not to scale and are generally intentionally simplified. To illustrate, integrated devices can have many tens or hundreds of contacts and corresponding interconnections; however, a very small number of such contacts and interconnects are illustrated herein to highlight important features of the disclosure without unduly complicating the drawings.

Particular aspects of the present disclosure are described below with reference to the drawings. In the description, common features are designated by common reference numbers. As used herein, various terminology is used for the purpose of describing particular implementations only and is not intended to be limiting of implementations. For example, the singular forms “a,” “an,” and “the” are intended to include the plural forms as well, unless the context clearly indicates otherwise. Further, some features described herein are singular in some implementations and plural in other implementations. For ease of reference herein, such features are generally introduced as “one or more” features and are subsequently referred to in the singular or optional plural (as indicated by “(s)”) unless aspects related to multiple of the features are being described.

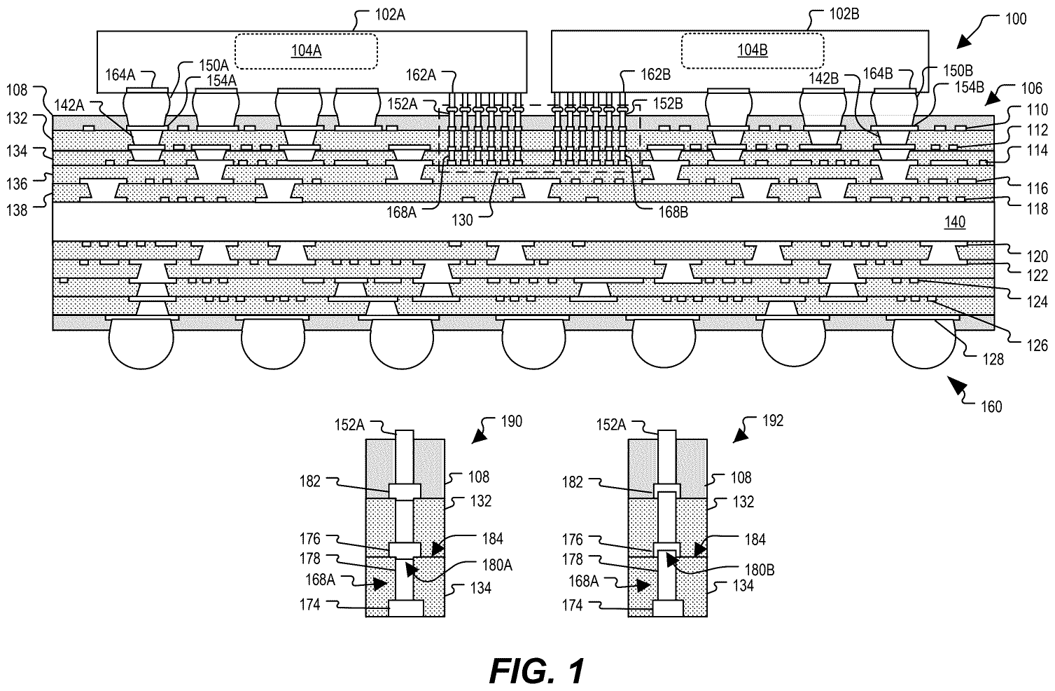

In some drawings, multiple instances of a particular type of feature are shown. In some circumstances, fewer than all of such features may be identified using a reference number. For example, a single reference number may be shown and associated with a representative instance of the feature so as not to obscure other aspects of the drawings. Where the physical and/or logical distinction between similar features is important, the same reference number may be used for each such feature, and the different instances may be distinguished by addition of a letter to the reference number. When the features as a group or a type are referred to herein (e.g., when no particular one of the features is being referenced), the reference number is used without a distinguishing letter. However, when one particular feature of multiple features of the same type is referred to herein, the reference number is used with the distinguishing letter. For example, referring to FIG. 1, multiple dies are illustrated and associated with reference numbers 102A and 102B. When referring to a particular one of these dies, such as a die 102A, the distinguishing letter “A” is used. However, when referring to any arbitrary one of these dies or to these dies as a group, the reference number 102 is used without a distinguishing letter.

As used herein, the terms “comprise,” “comprises,” and “comprising” may be used interchangeably with “include,” “includes,” or “including.” As used herein, “exemplary” indicates an example, an implementation, and/or an aspect, and should not be construed as limiting or as indicating a preference or a preferred implementation. As used herein, an ordinal term (e.g., “first,” “second,” “third,” etc.) used to modify an element, such as a structure, a component, an operation, etc., does not by itself indicate any priority or order of the element with respect to another element, but rather merely distinguishes the element from another element having a same name (but for use of the ordinal term). As used herein, the term “set” refers to one or more of a particular element, and the term “plurality” refers to multiple (e.g., two or more) of a particular element.

Improvements in manufacturing technology and demand for lower cost and more capable electronic devices has led to increasing complexity of integrated circuits (ICs). Often, more complex ICs have more complex interconnection schemes to enable interaction between ICs of a device. The number of interconnect levels for circuitry has substantially increased due to the large number of devices that are now interconnected in a state-of-the-art mobile application device.

These interconnections include back-end-of-line (BEOL) interconnect layers, which may refer to the conductive interconnect layers for electrically coupling to front-end-of-line (FEOL) active devices of an IC. The various BEOL interconnect layers are formed at corresponding BEOL interconnect levels, in which lower BEOL interconnect levels generally use thinner metal layers relative to upper BEOL interconnect levels. The BEOL interconnect layers may electrically couple to middle-of-line (MOL) interconnect layers, which interconnect to the FEOL active devices of an IC.

State-of-the-art mobile application devices demand a small form factor, low cost, a tight power budget, and high electrical performance. Mobile package design has evolved to meet these divergent goals for enabling mobile applications that support multimedia enhancements. One approach to reducing package size is to integrate multiple dies within a single package. One example of a multi-die packages is a two-dimensional (2D) package architecture, in which two or more dies are coupled to a package substrate side-by-side with one another. Dies in this configuration can interact with one another (e.g., via die-to-die connections) and with off-package devices (e.g., via off-package connections). A challenge of such configurations is that die-to-die and off-package connections have different design criteria. For example, off-package connections are generally larger (e.g., in terms of line width, line spacing, etc.) than is needed for die-to-die connections. Various workarounds have been used to address this size difference. For example, additional devices (e.g., interposer devices or bridge die) can be added to a package to route die-to-die connections using smaller lines. As another example, additional layers or a separate stacked substrate can be added to the package substrate to provide die-to-die connection and redistribution routing to connect to off-package connections.

Another approach to reducing package size is a 2.5D architecture, in which two or more devices are positioned side-by-side with one another on the package substrate, and one or more additional devices are stacked on at least one of the side-by-side devices. To illustrate, a stacked die arrangement can be coupled to a package substrate side-by-side with another die, a passive device, another die stack, etc. Stacked die schemes and chiplet architectures are becoming more common as significant power performance area (PPA) yield enhancements are demonstrated for stacked die and chiplet architecture product lines.

Various challenges are associated with reducing package size in a multi-die package using a 2D package architecture. For example, conventional layer-to-layer connections are formed in the substrate using a laser drilling process during via formation. The capability and registration accuracy of laser drilling mechanisms results in relatively large vias and pad diameters. For multi-die connection, a relatively large number of connections are required to interconnect the dies, but the routing required for the such a large number of connections may not be feasible using conventional package design rules. Providing such routing requires fine line and space (L/S) characteristics and a relatively large number of layers for the routing, with vias providing layer-to-layer connections for the routing.

Various aspects of the present disclosure provide a device that includes a conductive pillar structure for die interconnection that addresses many of the challenges with multi-die packages. For example, the conductive pillar structure is configured to provide signal paths between two or more dies coupled to a package substrate using conductive pillar (e.g., copper pillars) processing techniques to form layer-to-layer connections with reduced dimensions as compared to conventional vias. The reduced dimensions enables a larger number of traces to be routed between the pillars of each layer, reducing the number of layers required to carry the die-to-die routing. A technical benefit achieved by use of this arrangement is that a large number of die-to-die signal paths can be provided in a small region of the substrate, enabling increased performance due to increased interconnection between the dies without a corresponding increase in package size. The reduced dimensions may also enable the die-to-die connections to be formed using relatively larger line and space characteristics, providing improved power and thermal performance as compared to alternative approaches such as redistribution layers.

As used herein, the term “layer” includes a film, and is not construed as indicating a vertical or horizontal thickness unless otherwise stated. As used herein, the term “chiplet” may refer to an integrated circuit block, a functional circuit block, or other like circuit block specifically designed to work with one or more other chiplets to form a larger, more complex chiplet architecture.

### Exemplary Device Including a Conductive Pillar Structure for Die Interconnection

FIG. 1 illustrates an example of a device 100 that includes multiple dies 102 coupled to a substrate 106. In FIG. 1, the dies 102 include a die 102A and a die 102B. Each die 102 can include circuitry 104, such as a plurality of transistors and/or other circuit elements arranged and interconnected to form a power distribution network (PDN), logic cells, memory cells, etc. Components of the circuitry 104 can be formed in and/or over a semiconductor substrate of the die 102. Different implementations can use different types of transistors, such as a field effect transistor (FET), planar FET, finFET, a gate all around FET, or mixtures of transistor types. In some implementations, a front end of line (FEOL) process may be used to fabricate the integrated circuitry 104 in and/or over the semiconductor substrate to form each of the dies 102.

The circuitry 104 of each die 102 is electrically connected to a set of contacts of the die 102. The contacts of the die 102A in FIG. 1 include contacts 162A (e.g., conductive pillars with micro-bumps) that are configured to be electrically connected to contacts 162B of the die 102B and also include contacts 164A (e.g., conductive pads) that are configured to be coupled, via the substrate 106, to off-package devices by way of contacts of the substrate 106 (e.g., a ball grid array (BGA) 160 in FIG. 1). Likewise, the contacts of the die 102B include contacts 162B that are configured to be electrically connected to the contacts 162A of the die 102A and also include contacts 164B that are configured to be coupled, via the substrate 106, to off-package devices by way of the contacts of the BGA 160. In a particular aspect, as described further below, die-to-die connections, such as signal paths between the contacts 162A and 162B are routed through an embedded interconnect structure within a die-to-die interconnect region 130 of the substrate 106.

The substrate 106 includes a stacked set of layers including metal layers and dielectric layers. Adjacent metal layers are separated from one another by one or more dielectric layers, and patterned to define metal lines. The metal lines are interconnected by conductive vias and conductive pillars to define conductive paths through the substrate 106. In the specific example illustrated in FIG. 1, which is illustrative and not limiting, the substrate 106 includes a set of metal layers, including a metal layer 110 (e.g., an M1 layer), a metal layer 112 (e.g., an M2 layer), a metal layer 114 (e.g., an M3 layer), a metal layer 116 (e.g., an M4 layer), a metal layer 118 (e.g., an M5 layer), a metal layer 120 (e.g., an M6 layer), a metal layer 122 (e.g., an M7 layer), a metal layer 124 (e.g., an M8 layer), a metal layer 126 (e.g., an M9 layer), a metal layer 128 (e.g., an M10 layer), and a core 140. In FIG. 1, adjacent metal layers are separated from one another by a dielectric layer, such as a dielectric layer 132 between the metal layer 110 and the metal layer 112, a dielectric layer 134 between the metal layer 112 and the metal layer 114, a dielectric layer 136 between the metal layer 114 and the metal layer 116, and a dielectric layer 138 between the metal layer 116 and the metal layer 118, and electrically connected through one or more conductive vias, such as conductive vias 142, and/or through one or more conductive pillars, such as conductive pillars 168.

FIG. 1 also illustrates a solder resist layer 108 on a first side (e.g., a top side in the orientation illustrated in FIG. 1) of the substrate 106 defining openings through which the contacts 150 (e.g., contacts 150A and 150B) and conductive pillars 152 (e.g., conductive pillars 152A and 152B) extend. Similarly, a solder resist layer on a second side (e.g., a bottom side in the orientation illustrated in FIG. 1) of the substrate 106 defines openings to the metal layer 128 through which solder balls of the BGA 160 are coupled to the substrate 106.

A first set of conductors form conductive paths between the contacts 162. The first set of conductors includes a first set of metal lines and conductive pillars within the die-to-die interconnect region 130. For example, in FIG. 1, the first set of conductors includes, within the die-to-die interconnect region 130, metal lines defined within the metal layer 110, metal lines defined within the metal layer 112, metal lines defined within the metal layer 114, and conductive pillars 168 therebetween. A second set of conductors, distinct from the first set of conductors and including a second set of metal lines among the metal layers 110-128 and conductive vias therebetween (e.g., conductive vias 142), form conductive paths between the BGA 160 and the contacts 164 of the dies 102.

The first set of metal lines and conductive pillars 168 of the die-to-die interconnect region 130 are electrically connected to the conductive pillars 152, illustrated as a set of conductive pillars 152A configured to be electrically connected to the die 102A and a set of conductive pillars 152B configured to be electrically connected to the die 102B. The set of conductive pillars 152A and the set of conductive pillars 152B extend from a surface of the substrate 106 and connect to the contacts 162A of the die 102A and the contacts 162B of the die 102B, respectively. A set of conductive pillars 168A interconnect the first set of metal lines to the conductive pillars 152A, and a set of conductive pillars 168B interconnect the first set of metal lines to the set of conductive pillars 152B, to interconnect the die 102A to the die 102B.

A diagram 190 illustrates a first non-limiting example of a portion of the first set of conductors in the die-to-die interconnect region 130. A conductive pillar 168A includes a conductive material 178 extending through the dielectric layer 134 from a lower line 174 formed at a lower metal layer (the metal layer 114) to an upper line 176 formed at an upper metal layer (the metal layer 112). Similarly, a conductive material extends through the dielectric layer 132 from the line 176 to a line 182 formed at the metal layer 110. A conductive pillar 152A is formed on the line 182 and extends through the solder resist layer 108 to protrude from the upper surface of the substrate 106.

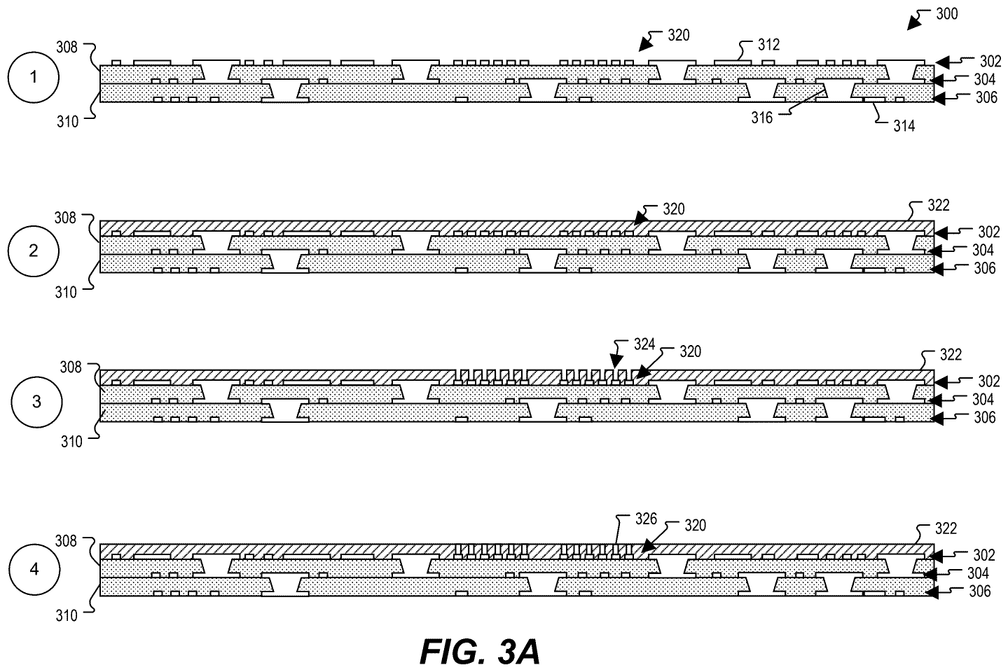

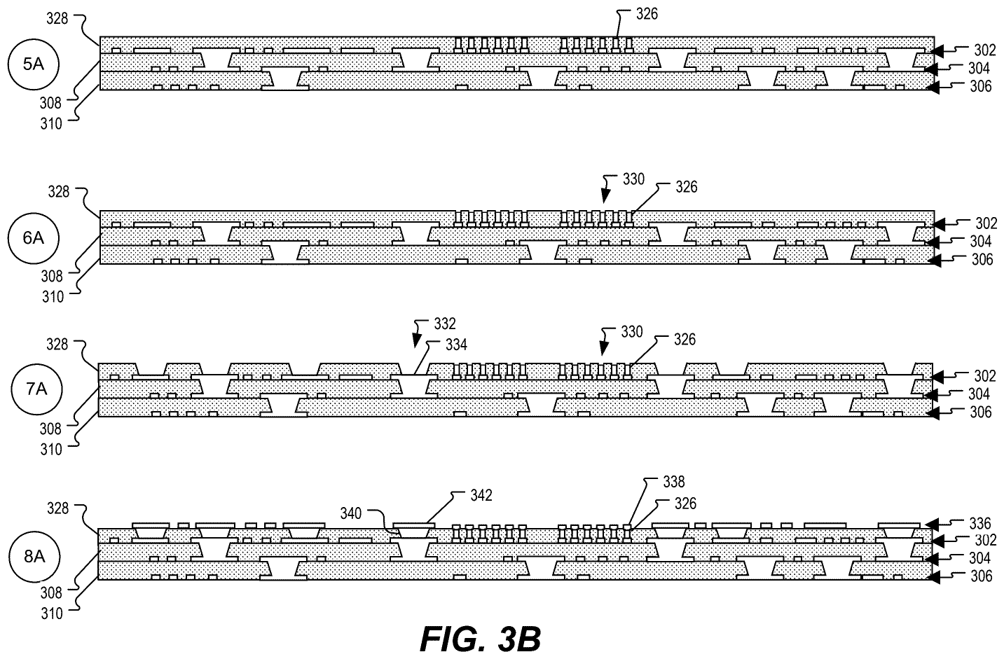

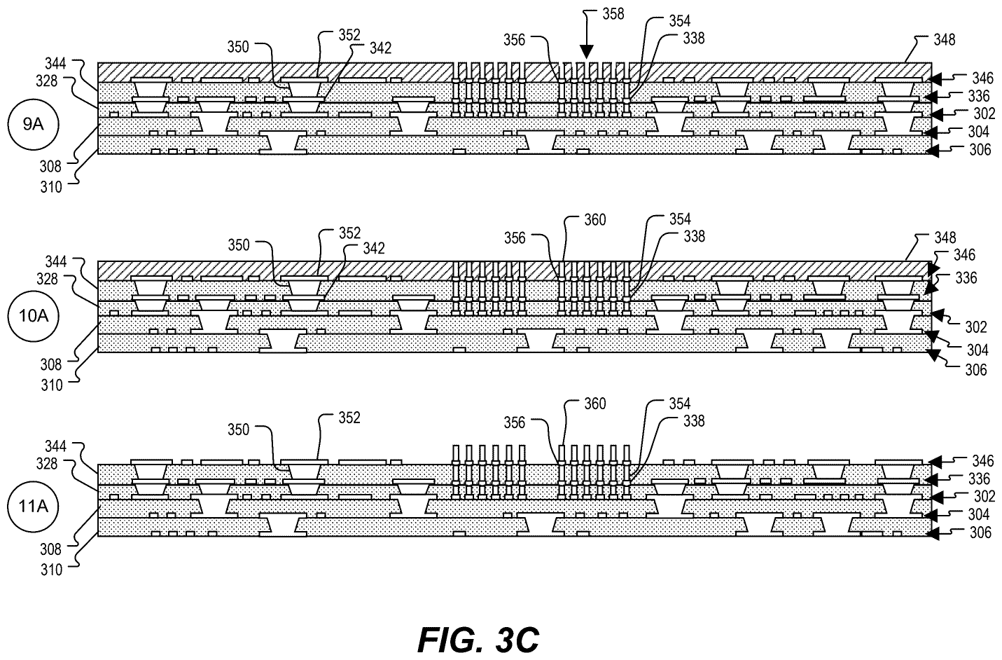

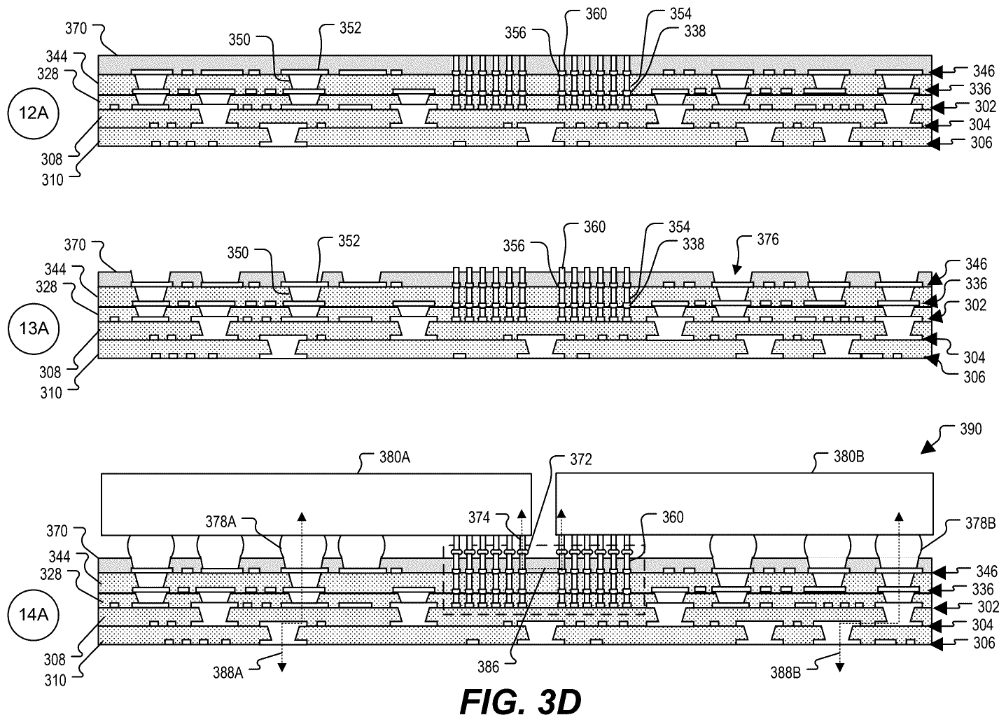

As illustrated in the diagram 190, an interface 180A between the line 176 and the conductive material 178 is below an upper surface 184 of the dielectric layer 134. For example, during formation of the substrate 106, processing including a soft etch results in the top of the conductive material 178 being recessed lower than the upper surface 184 of the dielectric layer 134. When the line 176 is formed, metal applied on the upper surface 184 extends into the recess to contact the conductive material and form the interface 180A. Similar processing is performed during formation of the line 182 and is described in further detail with reference to the fabrication sequence of FIGS. 3A-3D.

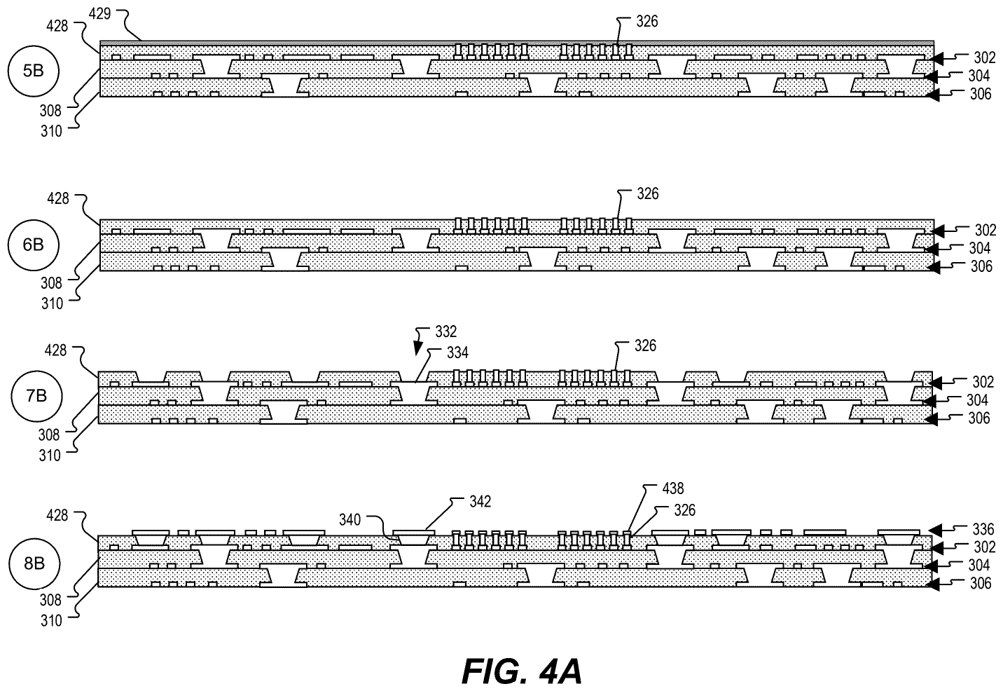

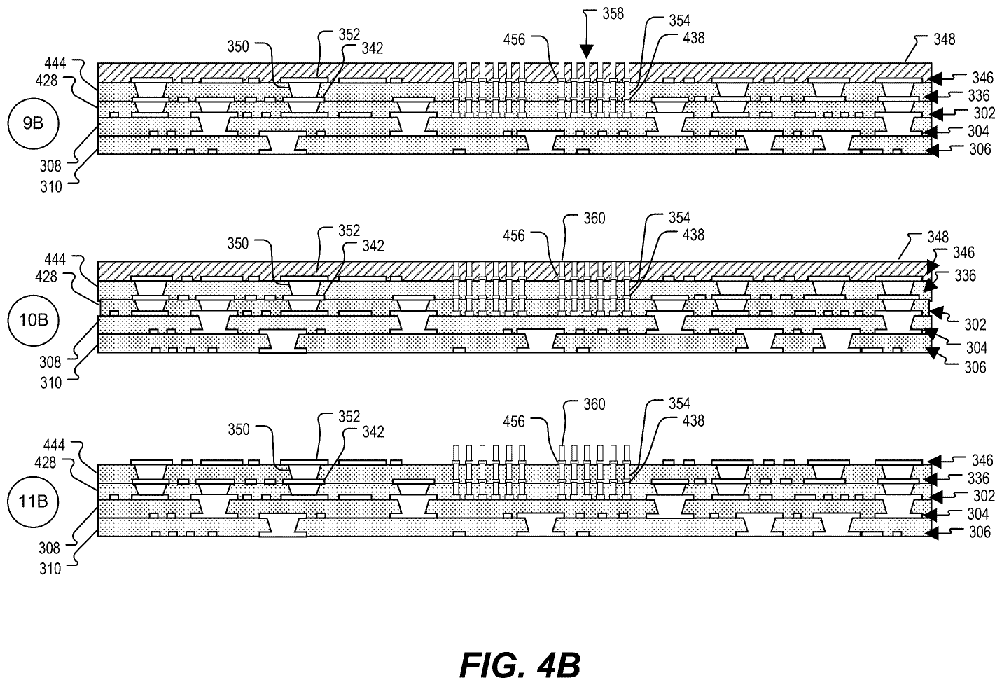

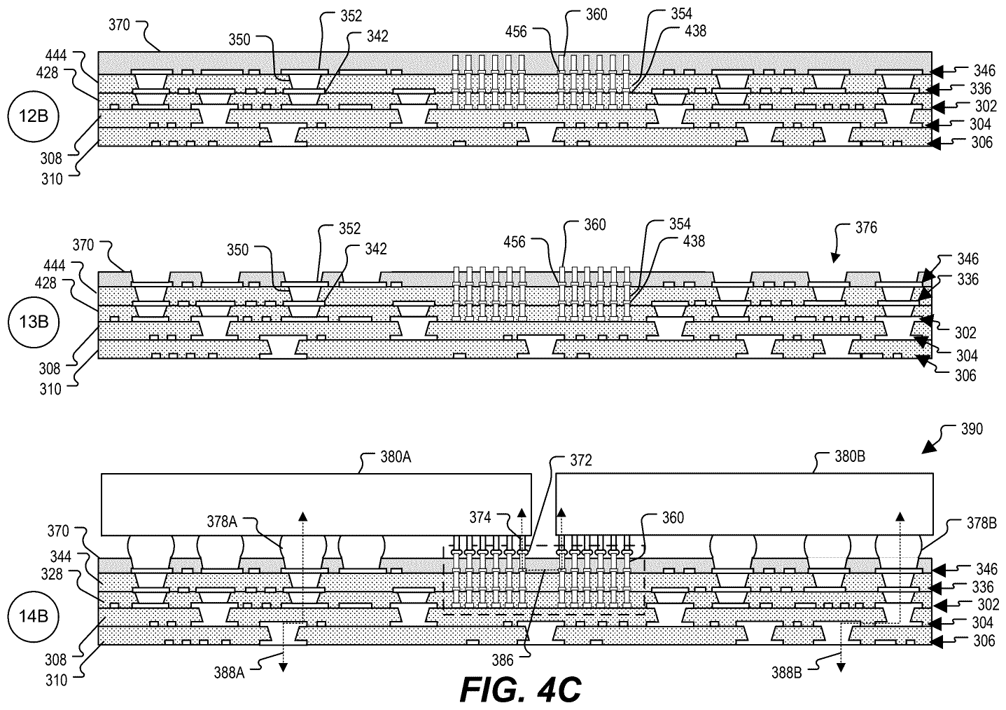

A diagram 192 depicts an alternative example in which a portion of the conductive material 178 extends above the upper surface 184 of the dielectric layer 134 to form an interface 180B with the upper line 176. In this example, the dielectric layer 134 may be a lower layer of a two-layer dielectric laminate that is applied over the conductive material 178. The upper layer of the two-layer dielectric laminate is removed, exposing the upper surface 184 and the upper end of the conductive material 178 protruding from the upper surface 184. When the upper line 176 is formed, metal applied on the upper surface 184 forms around the protruding portion of the conductive material 178 and forms the interface 180B. Similar processing is performed during formation of the line 182 and is described in further detail with reference to the fabrication sequence of FIGS. 4A-4C.

In the diagrams 190 and 192, the line 182, the line 176, and the line 174 are formed in the metal layer 110, the metal layer 112, and the metal layer 114, respectively, using metal line processing techniques, such as lithography and etching, with higher accuracy that enables smaller size and spacing dimensions as compared to conventional substrate pad and via processing. such as conventional laser drilling to form via openings through dielectric layers.

Although not illustrated in FIG. 1, one or more of the line 182, the line 176, or the line 174 is connected to the set of conductive pillars 168B by one or more of the first set of metal lines and, in some cases, by one or more conductive pillars, to provide a signal propagation path between a contact 162A of the die 102A and a contact 162B of the die 102B.

In addition to the conductive pillars 152 and the conductive pillars 168 connected to the first metal lines in the die-to-die interconnect region 130, the substrate 106 also includes a set of pads 154A configured to be electrically connected to the die 102 and a set of pads 154B configured to be electrically coupled to the die 102B. As illustrated, an electrical contact 150A, such as a solder ball, electrically connects a pad 154A and a corresponding contact 164A of the die 102A. Similarly, an electrical contact 150B electrically connects a pad 154B and a corresponding contact 164B of the die 102B.

The second set of conductors, including the second set of metal lines and the conductive vias 142, form conductive paths between contacts 164 of the dies 102 and the BGA 160. For example, the set of conductive vias 142A interconnect the second set of metal lines to the set of pads 154A, and the set of conductive vias 142B interconnect the second set of metal lines to the set of pads 154B.

The second set of conductors are sized and arranged to provide off-package connections, such as conductive paths for power, ground, and off-package input/output (I/O), while the first set of conductors of the die-to-die interconnect region 130 are sized and arranged to provide die-to-die connections. For example, the use of metal pillars (e.g., copper pillars) for the conductive pillars 152 and the conductive pillars 168 enables a reduced bump pitch (e.g., a smallest spacing between the conductive pillars 152) in the die-to-die interconnect region 130 as compared to using conventional layer-to-layer via connections; e.g., the bump pitch of the conductive pillars 152 is smaller than the bump pitch of the pads 154. As a result, the substrate 106 provides a higher contact density in the die-to-die interconnect region 130.

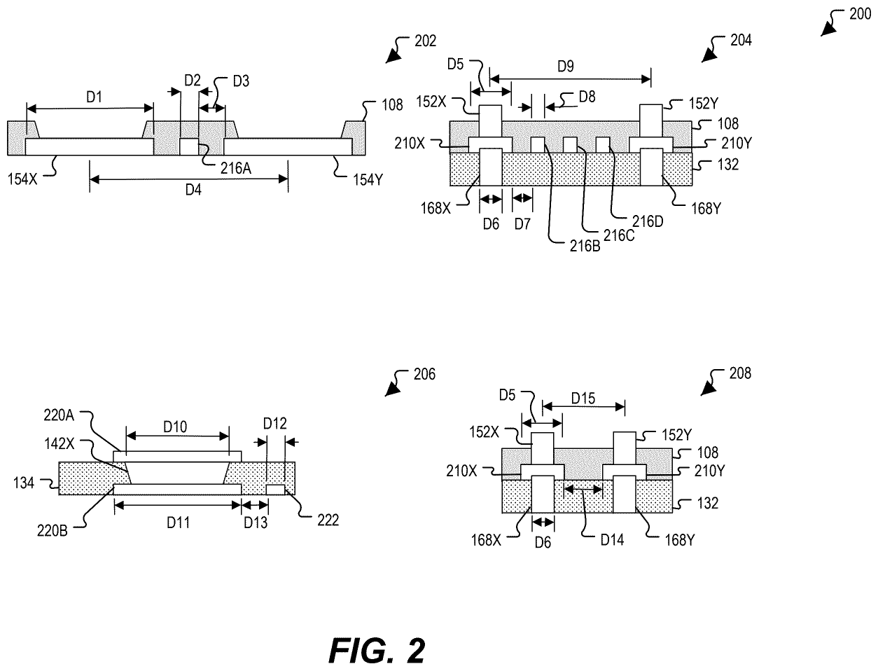

Additionally, the first set of metal lines and the pillars 168 of the die-to-die interconnect region 130 have first characteristic dimensions (e.g., line width and line spacing, pillar width and pillar spacing) selected to, among other things, provide a large number of signal paths in a small area, and the second set of metal lines and the vias 142 have second characteristic dimensions (e.g., line width and line spacing, via width and via spacing, via pad width and via pad spacing) selected to, among other things, provide target current carrying capacity and to enable use of standard manufacturing techniques. In a particular aspect, one or more of the first characteristic dimensions are smaller than their counterparts among the second characteristic dimensions. For example, lines having vertical connections to pillars within the die-to-die interconnect region 130 have a smaller horizontal dimension than via pads for the vias 142, which enables, for similar pitches, a larger number of metal lines (“escape lines”) to be routed between adjacent conductive pillars 152 and between adjacent pillars 168 than can be routed between adjacent pads 154 and between adjacent vias 142, as described further with reference to FIG. 2.

One technical benefit of using the conductive pillars 152 and the conductive pillars 168 is that the smaller horizontal dimensions enable routing of a larger number of signal paths between the dies 102 with little or no increase in the dimensions of the substrate 106. The higher spatial density of the conductive pillars 152 reduces a footprint on the surface of the substrate 106 for the die-to-die contacts, and also enables the use of shorter signal paths between the contacts 162A and the contacts 162B as compared to using a conventional pad and via structure. Increasing the number of signal paths between the dies 102 and shortening the lengths of the signal paths generally favors increase in performance of the device 100. In addition, the smaller dimensions of the conductive pillars 152, 168, and associated lines, enables a larger number of escape lines in the die-to-die interconnect region 130, which enables interconnection of the dies 102 using a smaller number of layers and thereby reducing the overall size of the device 100 relative to a conventional device.

Although FIG. 1 illustrates a single die-to-die interconnect region 130, in other examples, the device 100 includes more than one die-to-die interconnect region 130. To illustrate, a third die (or another device) can be coupled to the substrate 106 and interconnected with either or both of the dies 102 via another die-to-die interconnect region having a similar conductive pillar structure as described for the die-to-die interconnect region 130.

Although the region 130 is referred to herein as a die-to-die interconnect region 130, in other examples, the conductive pillars 152, 168 of the region 130 are used to interconnect other types of devices, such as to connect a die to a passive device or to connect two passive devices. Furthermore, although the die-to-die interconnect region 130 is illustrated in FIG. 1 as including two dielectric layers 132, 134 between three metal layers 110, 112, and 114, in other examples, the die-to-die interconnect region 130 includes more than three or fewer than three metal layers. Likewise, although the substrate 106 is illustrated in FIG. 1 as including ten metal layers 110, 112, 114, 116, 118, 120, 122, 124, 126, and 128, in other examples, the substrate 106 includes more than ten or fewer than ten metal layers.

In some implementations, the device 100 can be integrated with one or more other devices to form an integrated packaged device. For example, the substrate 106 can correspond to an upper substrate or a lower substrate of a package-on-package device. To illustrate, when the substrate 106 corresponds to a lower substrate of a package-on-package device, another substrate can be positioned over the dies 102 and electrically connected to the metal layer 110 via interposer conductors.

In some implementations, the dies 102 can correspond to chiplets which are interconnected via the die-to-die interconnect region 130. Alternatively, one of the dies 102 can be a bottom chiplet of a stacked chiplet arrangement. In such a stacked chiplet arrangement, another die (i.e., another chiplet) is stacked on top of and electrically connected to one of the dies. Using chiplets arranged and interconnected as a 3D stack can provide various benefits as compared to providing the same functional circuitry in one monolithic chip. For example, each chiplet is smaller than a monolithic die including all of the same functional circuit blocks would be. Since yield loss in IC manufacturing tends to increase as the die size increases, using smaller dies can reduce yield loss (i.e., increase yield) of the IC manufacturing process. Another benefit is that the chiplets can be fabricated in different locations and/or by different manufacturers, and in some cases, using different fabrication technologies (e.g., different fabrication technology nodes). As an example, one die 102 of a chiplet-based integrated device can include components (e.g., interconnects, transistors, etc.) that have a first minimum size, and another die of the chiplet-based integrated device can include components (e.g., interconnects, transistors, etc.) that have a second minimum size, where the second minimum size is greater than the first minimum size. In contrast, all of the circuitry of a monolithic die is fabricated using the same fabrication technologies and equipment. As a result, when manufacturing a monolithic die, the entire die may be subject to the tightest manufacturing constraint of the most complex component of the monolithic die. In contrast, when using chiplets, different chiplets can be manufactured using different fabrication technologies (e.g., different fabrication technology nodes), and only the chiplet or chiplets that include the most complex components are subjected to the tightest manufacturing constraints. In this arrangement, chiplets fabricated using less expensive and/or higher yield fabrication technologies can be integrated with chiplets fabricated using more expensive and/or lower yield fabrication technologies to form an integrated device, resulting in overall savings. Still further, in some cases, as technology improves, the design of one or both of the chiplets can be changed such that new chiplet design is integrated with an older chiplet design, which improves manufacturing flexibility and reduces design costs.

In various implementations, the device 100 can include components such as a power management integrated circuit (PMIC), an application processor (including one or more processor cores), a modem, a radio frequency (RF) device, a passive device, a filter, a capacitor, an inductor, a transmitter, a receiver, a gallium arsenide (GaAs) based integrated device, a surface acoustic wave (SAW) filter, a bulk acoustic wave (BAW) filter, a light emitting diode (LED) integrated device, a silicon (Si) based integrated device, a silicon carbide (SiC) based integrated device, a memory (including multiple memory cells), power management processor, and/or combinations thereof. In such implementations, the dies 102 can operate as any of these components (or a combination of these components) that includes active circuitry.

FIG. 2 illustrates cross-sectional profile views of contacts and vias that may be included in the device 100.

A first diagram 202 illustrates a pad 154X and an adjacent pad 154Y of the set of contact pads 154. Each of the pads 154X, 154Y has a horizontal dimension (pad width) D1, which may be sized to receive solder material within the corresponding opening of the solder resist layer 108. An escape line 216A is between the pads 154X and 154Y. The escape line 216A has a horizontal dimension (line width) D2 and is separated from each of the pads 154X, 154Y by a horizontal dimension (spacing) D3. A resulting pad-to-pad pitch (e.g., bump pitch) D4 is determined by the expression: D1+D3+D2+D3.

In an illustrative, non-limiting example, a minimum pad width (D1) is 80 micrometers (um), a minimum line width (D2) is 8 um, and a minimum spacing dimension (D3) is 11 um. In this example, the minimum bump pitch D4 is 110 um, which can be too large to accommodate a sufficient number of die-to-die interconnections within a given die footprint or may require multiple additional layers to route signal paths between the dies 102 due to only having a single escape line 216A between the pads 154X, 154Y.

A second diagram 204 illustrates a conductive pillar 152X and an adjacent conductive pillar 152Y of the set of conductive pillars 152. A line 210X electrically connects the conductive pillar 152X to a pillar 168X of the set of pillars 168, and a line 210Y electrically connects the conductive pillar 152Y to a pillar 168Y of the set of pillars 168. Each of the lines 210X, 210Y has a horizontal dimension (width) D5, and each of the conductive pillars 152X, 152Y, 168X, and 168Y has a horizontal dimension (D6). Multiple metal lines, illustrated as three escape lines 216B, 216C, 216D, are positioned between the conductive pillars 152X and 152Y. Each of the escape lines 216B, 216C, and 216D has a horizontal dimension (line width) D8 and is separated from adjacent structures by a horizontal dimension (spacing) D7. A resulting pitch D9 is determined as: D5+3*D8+4*D7.

In an illustrative, non-limiting example, a minimum line width (D5) at pillar connections is 20 um, a minimum line width (D8) is 6 um, and a minimum spacing dimension (D7) is 8 um. In this example, a minimum pitch D9 is 70 um. Therefore, the conductive pillars illustrated in the second diagram 204 provide a larger number of escape lines between adjacent pillars with a smaller pitch as compared to the first diagram 202. The larger number of escape lines 216 enables die-to-die interconnections using fewer layers (and therefore a smaller substrate 106) as compared to using the conventional pad structure illustrated in the first diagram 202.

A third diagram 206 illustrates a via 142X of the conductive vias 142 extending through the dielectric layer 134 from an upper via pad 220A to a lower via pad 220B. The via 142X has a tapered profile that results from laser drilling an opening in the dielectric layer 134 to the lower via pad 220B. The via 142X has a horizontal dimension (largest width) D10, and each of the via pads 220A, 220B has a horizontal dimension (width) D11. A trace 222 has a horizontal dimension (line width) D12 and is separated from the lower via pad 220B by a horizontal dimension (spacing) D13.

In an illustrative, non-limiting example, a minimum largest via width D10 is 60 um, a minimum pad width (D10) is 90 um, a minimum line width (D12) is 8 um, and a minimum spacing dimension (D13) is 16 um. As a result, in this example, a minimum via-to-via spacing is 130 um.

The minimum value of the largest via width D10 (e.g., 60 um) and the pad width D11 (e.g., 90 um) may be limited by the laser capability and registration criteria. In contrast, the pillar structure of the second diagram 204 can be formed with much greater accuracy, such as a 5 um accuracy that allows use of a line having a width of 20 um for a pillar having a width of 10 um.

A fourth diagram 208 illustrates another example of the adjacent conductive pillars 152X, 152Y, lines 210X, 210Y, and pillars 168X, 168Y of the second diagram 204 without intervening escape lines. The line 210X is separated from the line 210Y by a horizontal dimension (spacing) D14. A resulting pitch D15 is determined as: D5+D14.

In an illustrative, non-limiting example, a minimum line width (D5) is 20 um, and a minimum spacing dimension (D14) is 20 um. In this example, the minimum pitch D14 is 40, which enables higher interconnection density as compared to using the conventional laser-drilled via structure illustrated in the third diagram 206. In the examples described with reference to the diagrams 202-208, therefore, a smallest spacing between pillars of the conductive pillars 152 is smaller than a smallest spacing between pads of set of pads 154, and a smallest spacing between pillars of the set of pillars 168 is smaller than a smallest spacing between vias of the set of vias 142.

Further, in the examples described with reference to the diagrams 202-208, the pads 154 have first characteristic dimensions (e.g., width, pitch) and the conductive pillars 152 have second characteristic dimensions (e.g., width, pitch), where the first characteristic dimensions of the pads 154 are greater than the second characteristic dimensions of the conductive pillars 152. In a particular example, the pitch of the pads 154 is greater than 90 um (e.g., 110 um in the first diagram 202 with one escape line, or 101 um with no escape lines), and the pitch of the conductive pillars 152 is less than 80 micrometers (e.g., 70 um with three escape lines, or 40 um with no escape lines). Likewise, the set of conductive pillars 168 have a first characteristic horizontal dimension (e.g., width, pitch) and the set of conductive vias 142 have a second characteristic horizontal dimension (e.g., largest width, pitch), where the first characteristic horizontal dimension of the set of conductive pillars 168 is smaller than the second characteristic horizontal dimension of the set of conductive vias 142.

### Exemplary Sequence for Fabricating a Device Including a Conductive Pillar Structure for Die Interconnection

In some implementations, fabricating a device that includes a conductive pillar structure includes several processes. FIGS. 3A, 3B, 3C, and 3D illustrate an exemplary sequence for providing or fabricating a device that includes a conductive pillar structure for die interconnection, as described with reference to FIG. 1 or FIG. 2. In some implementations, the sequence of FIGS. 3A-3D may be used to provide (e.g., during fabrication of) the device 100 of FIG. 1.

It should be noted that the sequence of FIGS. 3A-3D may combine one or more stages in order to simplify and/or clarify the sequence for providing or fabricating an integrated device. In some implementations, the order of the processes may be changed or modified. In some implementations, one or more of the processes may be replaced or substituted without departing from the scope of the disclosure. In the following description, reference is made to various illustrative Stages of the sequence, which are numbered (using circled numbers) in FIGS. 3A-3D.

Stage 1 of FIG. 3A illustrates a state after formation of a set of metal layers 300 of a substrate. A simplified set of metal layers 300 is illustrated in FIGS. 3A-3D (relative to FIG. 1) and includes a metal layer 302, a metal layer 304, and a metal layer 306. A dielectric layer 308 is between the metal layer 302 and the metal layer 304, and a dielectric layer 310 is between the metal layer 304 and the metal layer 306. The metal layers 302, 304, and 306 are patterned to form conductive lines, such as a metal line 312 of the metal layer 302 and a metal line 314 of the metal layer 306. In addition, the metal layer 302 is patterned to form lines 320, such as a pattern of copper pillar connections for copper pillar placement, such as the line 174 of FIG. 1. Conductive vias interconnect various ones of the metal lines. For example, a conductive via 316 through the dielectric layer 310 electrically connects a metal line of the metal layer 306 to a metal line of the metal layer 304. The conductive via 316 can correspond to a conductive via 142 of FIG. 1.

The set of metal layers 300 can be formed using a lamination process. For example, one or more of the metal layers 302, 304, and 306 can be formed concurrently using a symmetric lamination process. Alternatively, the set of metal layers 300 can be built up on a carrier substrate (not shown) or a core (e.g., the core 140 of FIG. 1) of the substrate. To illustrate, the metal layers 302, 304, and 306 can correspond to or include the metal layers 114, 116, and 118, respectively, of FIG. 1.

The metal layers 302, 304, and 306 can be patterned to define the metal lines (e.g., the metal lines 312, 314, and 320) using one or more subtractive processes (such as etching, engraving, or ablation of material of a metal layer), using one or more additive processes (such as printing or deposition), or using a combination of additive and subtractive processes. The additive or subtractive processes can use patterned mask layers, such as patterned dry films, to guide patterning of the metal layers 302, 304, 306 to define the metal lines. Each dielectric layer 308, 310 can correspond to a polymer layer or a pre-preg layer that is cured to form the respective dielectric layer(s) 308, 310. The conductive vias can be formed using drilling operations (e.g., laser drilling) to form openings, which are subsequently filled or coated with a conductive material (e.g., using a plating or deposition process) to form the conductive vias. In some implementations, plating or deposition guided by a mask layer can be used to concurrently form a metal layer and to fill an opening to form a conductive via.

The specific set of metal layers 300 illustrated in FIG. 3A is merely one example. In other implementations, Stage 1 ends with obtaining any type or configuration of package substrate that includes conductors (e.g., two or more metal layers and conductive vias therebetween) that form conductive paths between two sides of the set of metal layers 300.

Stage 2 illustrates a state after a mask layer 322 has been formed on the metal layer 302 and the dielectric layer 308. The mask layer 322 includes a dry film resist layer or another mask layer (e.g., a photoresist layer).

Stage 3 illustrates a state after the mask layer 322 is patterned to include openings 324 that expose the lines 320 (e.g., the pattern for copper pillar placement) using a photo process. For example, an exposure and development process may be applied to the mask layer 322 to form the openings 324.

Stage 4 illustrates a state after conductive pillars 326 have been formed in the openings 324. The conductive pillars 326 can be formed using plating operations and/or deposition operations guided by the mask layer 322 to apply conductive material (e.g., copper) within the openings 324 to contact the lines 320. The conductive pillars 326 may correspond to the conductive pillars 168 of the die-to-die interconnect region 130 of FIG. 1.

Stage 5A of FIG. 3B illustrates a state after the mask layer 322 has been removed and a dielectric layer 328 that encapsulates the conductive pillars 326 has been formed on the metal layer 302 and the dielectric layer 308. Removal of the mask layer 322 can be performed using one or more stripping, delamination, or ashing operations, or other operations appropriate for separating the mask layer 322 from adjoining structures, such as the conductive pillars 326, the metal layer 302 and/or the dielectric layer 308. The dielectric layer 328 can be formed using one or more lamination processes and may correspond to the dielectric layer 134 of FIG. 1.

Stage 6A illustrates a state after upper surfaces of the conductive vias 326 have been exposed. The dielectric layer 308 can be mechanically thinned using a grinding operation to reach the upper surfaces of the conductive pillars 326, and a soft etching operation (e.g., a relatively slow, finely controllable etching process) can be performed to remove residue on the surface of the dielectric layer 308 and etch the conductive material of the conductive pillars 326 to expose upper surfaces of the conductive material of the conductive pillars 326 in recesses 330 of the surface of the dielectric layer 328.

Stage 7A illustrates a state after the dielectric layer 328 is patterned to include openings 332 that expose via pads 334 in the metal layer 302. The openings 332 can be formed using a drilling process, such as laser drilling.

Stage 8A illustrates a state after conductive vias 340 have been formed in the openings 332 and a metal layer 336 has been patterned to from metal lines including lines 338 (e.g., copper pillar connections) on the pillars 326, and via pads 342 on the vias 340. The vias 340, the metal layer 336, or both, can be formed using a semi-additive process or other process and can include performing plating operations and/or deposition operations guided by a mask layer to apply conductive material (e.g., copper), followed by removal of the mask layer using one or more stripping, delamination, or ashing operations. The conductive material of the lines 338 extends within the recesses 330 to electrically connect with the conductive material of the pillars 326 such that an interface between the lines 338 and the conductive material of the pillars 326 is below the upper surface of the dielectric layer 328, such as described with reference to the diagram 190 of FIG. 1. According to an aspect, the metal layer 336 corresponds to the metal layer 112 of FIG. 1, the lines 338 correspond to the upper line 176 illustrated in the diagram 190, and the via 340 corresponds to a via 142.

Stages 2-8A can be repeated to add one or more additional layers.

Stage 9A of FIG. 3C illustrates a state after repeating Stages 2-8A to add a dielectric layer 344 and a metal layer 346, and after formation of a mask layer 348. Although Stage 9A illustrates a state after repeating a single cycle of the Stages 2-8A, in other embodiments multiple cycles of repeating Stages 2-8A may be performed to add additional layers.

The dielectric layer 344 is formed on the dielectric layer 328 and the metal layer 336. The dielectric layer 344 includes conductive vias 350 that are electrically connected to the via pads 342 and conductive pillars 354 that are electrically connected to the lines 338. The metal layer 346 is formed on the dielectric layer 344 and patterned to form pads 352 on the vias 350 and lines 356 (e.g., copper pillar connections) on the pillars 354. According to an aspect, the pads 352 correspond to the pads 154, and the lines 356 correspond to the line 182 illustrated in the diagram 190 of FIG. 1.

The mask layer 348 can be formed on the metal layer 346 and the dielectric layer 344. The mask layer 348 includes a dry film resist layer or another mask layer (e.g., a photoresist layer). The mask layer 348 is patterned to include openings 358 that expose the lines 356. For example, an exposure and development process may be applied to the mask layer 348 to form the openings 358.

Stage 10A illustrates a state after conductive pillars 360 have been formed in the openings 358. The conductive pillars 360 can be formed using plating operations and/or deposition operations guided by the mask layer 348 to apply conductive material (e.g., copper) within the openings 358 to contact the lines 356. According to an aspect, the conductive pillars 360 correspond to the conductive pillars 152 of FIG. 1.

Stage 11A illustrates a state after the mask layer 348 has been removed. Removal of the mask layer 348 can be performed using one or more stripping, delamination, or ashing operations, or other operations appropriate for separating the mask layer 348 from adjoining structures, such as the conductive pillars 360, the metal layer 346 and/or the dielectric layer 344.

Stage 12A of FIG. 3D illustrates a state after formation of a solder resist layer 370 that at least partially covers the conductive pillars 360 and covers the metal layer 346 and the dielectric layer 344. The solder resist layer 370 can be formed using one or more lamination processes or one or more liquid or gel application processes (e.g., spraying, rolling, dipping, or other coating operations).

Stage 13A illustrates a state after the solder resist layer 370 has been thinned to expose the top portions of the conductive pillars 360 and after openings 376 have been formed to expose the pads 352. The solder resist layer 370 can be thinned using a chemical etch down process that preserves the top portions of the conductive pillars 360. The openings 376 can be formed using a drilling process, such as laser drilling.

Stage 14A illustrates a state after dies 380 (including a die 380A and a die 380B) are attached to electrical contacts 378 and the conductive pillars 360 to form a device 390. In a particular implementation, the dies 380 include contact pads, which are coupled to the electrical contacts 378, and the electrical contacts 378 include solder bumps in the openings 376 that are heated to reflow the solder bumps to electrically connect the contact pads of the dies 380 to the pads 352. In a particular implementation, the dies 380 include conductive pillars 374 and solder bumps 372, such as microbumps, at the ends of conductive pillars 374. The solder bumps are heated to reflow the solder bumps to electrically connect the conductive pillars 374 to the conductive pillars 360.

Electrically connecting the dies 380 to the pads 352 provides conductive paths between the dies 380 and off-package contacts. For example, electrically connecting the die 380A to a contact 378A provides a conductive path 388A from the die 380A to an off-package contact, and electrically connecting the die 380B to a contact 378B provides a conductive path 388B from the die 380B to an off-package contact. Electrically connecting the dies 380 to the conductive pillars 360 provides conductive paths between the dies 380. For example, electrically connecting the die 380A and the die 380B to the conductive pillars 360 provides a conductive path 386 between the dies 380 through a die-to-die interconnect structure, such as the conductive pillar structure of the die-to-die interconnect region 130 of FIG. 1.

FIGS. 4A, 4B, and 4C illustrate stages of another exemplary sequence for providing or fabricating a device that includes a conductive pillar structure, as described with reference to FIG. 1. The sequence of FIGS. 4A-4C includes Stages 5B-14B as an alternative to the Stages 5A-14A of FIGS. 3B-3D and that may be used to provide (e.g., during fabrication of) the device 100 of FIG. 1.

The sequence begin with Stage 5B of FIG. 4A, which follows Stage 4 of FIG. 3B. Stage 5A illustrates a state after the mask layer 322 has been removed and a two-layer dielectric that encapsulates the conductive pillars 326 has been formed on the metal layer 302 and the dielectric layer 308. Removal of the mask layer 322 can be performed using one or more stripping, delamination, or ashing operations, or other operations appropriate for separating the mask layer 322 from adjoining structures, such as the conductive pillars 326, the metal layer 302 and/or the dielectric layer 308.

The two-layer dielectric includes a dielectric layer 428 and a “buttercoat” layer 429 (e.g., a resin layer, such as an epoxy layer), on the dielectric layer 428. The two-layer dielectric can be formed using one or more lamination processes, and the dielectric layer 428 may correspond to the dielectric layer 134 of FIG. 1.

Stage 6B illustrates a state after the buttercoat layer 429 has been removed to expose the upper surfaces of the conductive pillars 326. The buttercoat layer 429 can be removed by performing a desmear process to expose the upper portions of the conductive material of the conductive pillars 326, which extend above the upper surface of the dielectric layer 428.

Stage 7B illustrates a state after the dielectric layer 428 is patterned to include the openings 332 that expose the via pads 334 in the metal layer 302. The openings 332 can be formed using a drilling process, such as laser drilling.

Stage 8B illustrates a state after the conductive vias 340 have been formed in the openings 332 and the metal layer 336 has been patterned to from metal lines including lines 438 (e.g., copper pillar connections) on the pillars 326, and the via pads 342 on the vias 340. The vias 340, the metal layer 336, or both, can be formed using a semi-additive process or other process and can include performing plating operations and/or deposition operations guided by a mask layer to apply conductive material (e.g., copper), followed by removal of the mask layer using one or more stripping, delamination, or ashing operations.

The conductive material of the lines 438 encapsulates the exposed upper portions of the conductive material of the pillars 326 that protrude above the upper surface of the dielectric layer 428 so that an interface between the lines 438 and the conductive material of the pillars 326 is above the upper surface of the dielectric layer 328, such as described with reference to the diagram 192 of FIG. 1. According to an aspect, the metal layer 336 corresponds to the metal layer 112 of FIG. 1, the lines 438 correspond to the upper line 176 illustrated in the diagram 192, and the via 340 corresponds to a via 142.

The sequence of Stages 2, 3, 4, 5B, 6B, 7B, and 8B (e.g., Stages 2-8B) can be repeated to add one or more additional layers.

Stage 9B of FIG. 4B illustrates a state after repeating Stages 2-8B to add a dielectric layer 444 and the metal layer 346, and after formation of the mask layer 348. Although Stage 9B illustrates a state after repeating a single cycle of the Stages 2-8B, in other embodiments multiple cycles of repeating Stages 2-8B may be performed to add additional layers.

The dielectric layer 444 is formed on the dielectric layer 428 and the metal layer 336. The dielectric layer 444 includes the conductive vias 350 that are electrically connected to the via pads 342 and the conductive pillars 354 that are electrically connected to the lines 438. The metal layer 346 is formed on the dielectric layer 444 and patterned to form the pads 352 on the vias 350 and lines 456 (e.g., copper pillar connections) on the pillars 354. According to an aspect, the pads 352 correspond to the pads 154, and the lines 456 correspond to the line 182 illustrated in the diagram 192 of FIG. 1.

The mask layer 348 can be formed on the metal layer 346 and the dielectric layer 444. The mask layer 348 includes a dry film resist layer or another mask layer (e.g., a photoresist layer). The mask layer 348 is patterned to include the openings 358 that expose the lines 456. For example, an exposure and development process may be applied to the mask layer 448 to form the openings 358.

Stage 10B illustrates a state after the conductive pillars 360 have been formed in the openings 358. The conductive pillars 360 can be formed using plating operations and/or deposition operations guided by the mask layer 348 to apply conductive material (e.g., copper) within the openings 358 to contact the lines 456. According to an aspect, the conductive pillars 360 correspond to the conductive pillars 152 of FIG. 1.

Stage 11B illustrates a state after the mask layer 348 has been removed. Removal of the mask layer 348 can be performed using one or more stripping, delamination, or ashing operations, or other operations appropriate for separating the mask layer 348 from adjoining structures, such as the conductive pillars 360, the metal layer 346 and/or the dielectric layer 444.

Stage 12B of FIG. 4C illustrates a state after formation of the solder resist layer 370 that at least partially covers the conductive pillars 360 and covers the metal layer 346 and the dielectric layer 444. The solder resist layer 370 can be formed using one or more lamination processes or one or more liquid or gel application processes (e.g., spraying, rolling, dipping, or other coating operations).

Stage 13B illustrates a state after the solder resist layer 370 has been thinned to expose the top portions of the conductive pillars 360 and after openings 376 have been formed to expose the pads 352. The solder resist layer 370 can be thinned using a chemical etch down process that preserves the top portions of the conductive pillars 360. The openings 376 can be formed using a drilling process, such as laser drilling.

Stage 14B illustrates a state after the dies 380 (including the die 380A and the die 380B) are attached to the electrical contacts 378 and the conductive pillars 360 to form the device 390. In a particular implementation, the dies 380 include contact pads, which are coupled to the electrical contacts 378, and the electrical contacts 378 include solder bumps in the openings 376 that are heated to reflow the solder bumps to electrically connect the contact pads of the dies 380 to the pads 352. In a particular implementation, the dies 380 include the conductive pillars 374 and solder bumps 372, such as microbumps, at the lower end of the conductive pillars 374. The solder bumps are heated to reflow the solder bumps 372 to electrically connect the conductive pillars 374 to the conductive pillars 360.

Electrically connecting the dies 380 to the pads 352 provides conductive paths between the dies 380 and off-package contacts. For example, electrically connecting the die 380A to the contact 378A provides the conductive path 388A from the die 380A to an off-package contact, and electrically connecting the die 380B to the contact 378B provides the conductive path 388B from the die 380B to an off-package contact. Electrically connecting the dies 380 to the conductive pillars 360 provides conductive paths between the dies 380. For example, electrically connecting the die 380A and the die 380B to the conductive pillars 360 provides a conductive path 386 between the dies 380 through a die-to-die interconnect structure, such as the conductive pillar structure of the die-to-die interconnect region 130 of FIG. 1.

### Exemplary Flow Diagram of a Method for Fabricating a Device Including a Conductive Pillar Structure for Die Interconnection

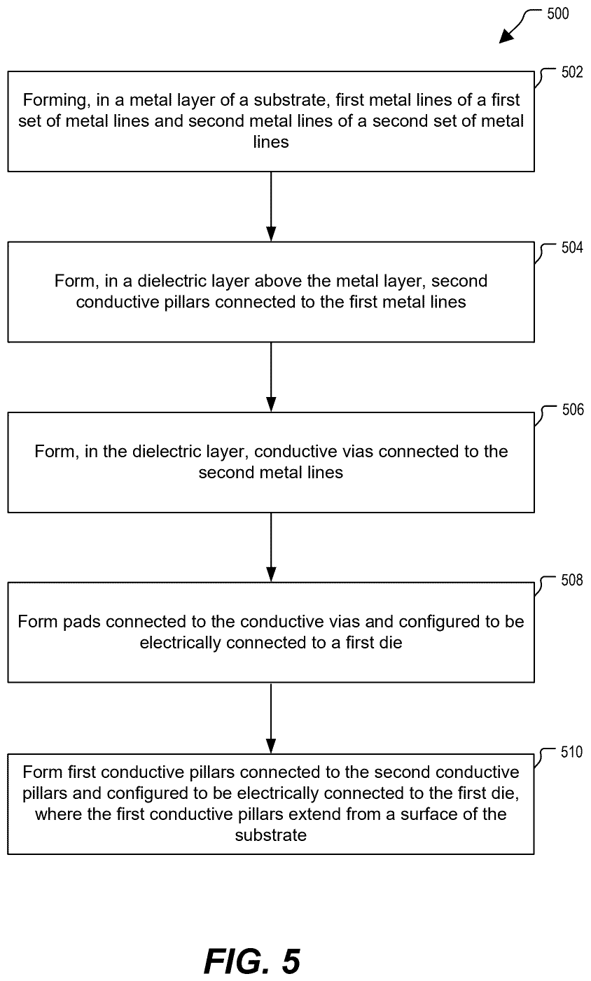

In some implementations, fabricating a device that includes a conductive post and via structure for die interconnection includes several processes. FIG. 5 illustrates an exemplary flow diagram of a method 500 for providing or fabricating a device that includes a conductive pillar structure. In some implementations, the method 500 may be used to provide or fabricate any of the device 100 of FIG. 1 or the device 390 of FIG. 3D or 4C. It should be noted that the method 500 of FIG. 5 may combine one or more processes in order to simplify and/or clarify the method for providing or fabricating an integrated device. In some implementations, the order of the processes may be changed or modified.

The method 500 includes, at block 502, forming, in a metal layer of a substrate, first metal lines of a first set of metal lines and second metal lines of a second set of metal lines. For example, the metal layer can correspond to the metal layer 112 of FIG. 1. The first set of metal lines can correspond to metal lines of the die-to-die interconnection region 130, and the second set of metal lines can correspond to metal lines coupled to the vias 142 providing signal paths to the BGA 160. Examples of operations that can be used to form the first metal lines and the second metal lines are described with reference to Stage 1 of FIG. 3A.

The method 500 includes, at block 504, forming, in a dielectric layer above the metal layer, second conductive pillars connected to the first metal lines. For example, the second conductive pillars can correspond to the conductive pillars 168 formed in the dielectric layer 132. Forming the second conductive pillars can include performing photoresist processing to form first holes in a photoresist layer above the metal layer, such as described with reference to forming the openings 324 of Stage 3 of FIG. 3A, and depositing conductive material of the second conductive pillars into the first holes, such as described with reference to forming the conductive pillars 326 of Stage 4 of FIG. 3A. Forming the second conductive pillars can also include removing the photoresist layer to expose the conductive material, and laminating the dielectric layer over the exposed conductive material, such as described with reference to forming the dielectric layer 328 of Stage 5A of FIG. 3B, or forming the two-layer dielectric including the dielectric layer 428 and the buttercoat layer 429 of Stage 5B of FIG. 4A.

In some embodiments, forming the second conductive pillars includes performing a soft etch to expose upper surfaces of the conductive material in recesses of an upper surface of the dielectric layer, such as described with reference to forming the recesses 330 of Stage 6A of FIG. 3B. In such embodiments, the method 500 also includes forming lines that contact the upper surfaces of the conductive material, where an interface between the lines and the conductive material is below the upper surface of the dielectric layer. For example, the lines can correspond to the upper line 176 illustrated in the diagram 190 of FIG. 1, and may be formed as described with reference to Stage 8A of FIG. 3B.

In some embodiments, forming the second conductive pillars includes performing a desmear process to expose upper portions of the conductive material by removing an epoxy layer from the dielectric layer, such as described with reference to removing the buttercoat layer 429 of Stage 5B of FIG. 4A. In such embodiments, the method 500 also includes forming lines that encapsulate the exposed upper portions of the conductive material, where the upper portions of the conductive material extend above an upper surface of the dielectric layer to form an interface with the lines. For example, the lines can correspond to the upper line 176 illustrated in the diagram 192 of FIG. 1, and may be formed as described with reference to Stage 8B of FIG. 4A.

The method 500 includes, at block 506, forming, in the dielectric layer, conductive vias connected to the second metal lines. For example, the conductive vias can include or correspond to the conductive vias 142 of FIG. 1. According to an aspect, the second conductive pillars have a smaller horizontal dimension than the conductive vias. Forming the conductive vias can include forming second holes in the dielectric layer using a laser drilling process, and depositing conductive material of the conductive vias into the second holes. Examples of operations that can be used to form the conductive vias are described with reference to Stages 7A-8A of FIG. 3B or Stages 7B-8B of FIG. 4A.

The method 500 includes, at block 508, forming pads connected to the conductive vias and configured to be electrically connected to a first die. For example, the pads can include or correspond to the pads 154 of FIG. 1. Examples of operations that can be used to form the pads are described with reference to Stage 8A of FIG. 3B or Stage 8B of FIG. 4A.

The method 500 includes, at block 510, forming first conductive pillars connected to the second conductive pillars and configured to be electrically connected to the first die, where the first conductive pillars extend from a surface of the substrate. For example, the first conductive pillars can correspond to the conductive pillars 152 of FIG. 1. Examples of operations that can be used to form the first conductive pillars are described with reference to Stages 9A-11A of FIG. 4A or Stages 9B-11B of FIG. 4B.

In some implementations, the method also includes forming a solder resist layer on the dielectric layer, and forming openings in the solder resist layer using a laser drilling process to expose an upper surface of the pads. The first conductive pillars protrude above an upper surface of the solder resist layer. For example, the solder resist layer can correspond to the solder resist layer 108 of FIG. 1. Examples of operations that can be used to form the solder resist layer and the openings are described with reference to Stages 12A and 13A of FIG. 3D or Stages 12B and 13B of FIG. 4C.

### Exemplary Electronic Devices

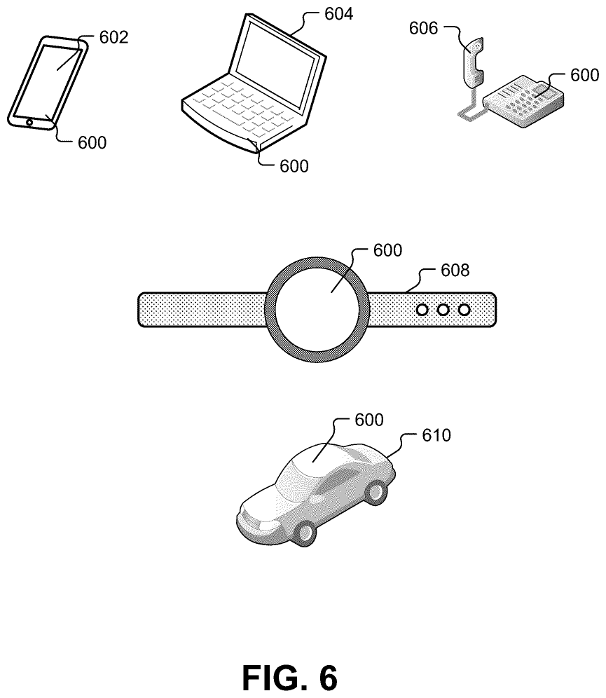

FIG. 6 illustrates various electronic devices that may include or be integrated with the device 100 of FIG. 1 or the device 390 of FIG. 3D or FIG. 4C. For example, a mobile phone device 602, a laptop computer device 604, a fixed location terminal device 606, a wearable device 608, or a vehicle 610 (e.g., an automobile or an aerial device) may include a device 600. The device 600 can include, for example, the device 100 of FIG. 1, the device 390 of FIG. 3D or FIG. 4C, or other devices described herein. The devices 602, 604, 606, and 608 and the vehicle 610 illustrated in FIG. 6 are merely exemplary. Other electronic devices may also feature the device 600 including, but not limited to, a group of devices (e.g., electronic devices) that includes mobile devices, hand-held personal communication systems (PCS) units, portable data units such as personal digital assistants, global positioning system (GPS) enabled devices, navigation devices, set top boxes, music players, video players, entertainment units, fixed location data units such as meter reading equipment, communications devices, smartphones, tablet computers, computers, wearable devices (e.g., watches, glasses), Internet of things (IoT) devices, servers, routers, electronic devices implemented in vehicles (e.g., autonomous vehicles), or any other device that stores or retrieves data or computer instructions, or any combination thereof.

One or more of the components, processes, features, and/or functions illustrated in FIGS. 1-6 may be rearranged and/or combined into a single component, process, feature or function or embodied in several components, processes, or functions. Additional elements, components, processes, and/or functions may also be added without departing from the disclosure. It should also be noted FIGS. 1-6 and its corresponding description in the present disclosure is not limited to dies and/or ICs. In some implementations, FIGS. 1-6 and its corresponding description may be used to manufacture, create, provide, and/or produce devices and/or integrated devices. In some implementations, a device may include a die, an integrated device, an integrated passive device (IPD), a die package, an integrated circuit (IC) device, a device package, an integrated circuit (IC) package, a wafer, a semiconductor device, a package-on-package (PoP) device, a heat dissipating device and/or an interposer.

It is noted that the figures in the disclosure may represent actual representations and/or conceptual representations of various parts, components, objects, devices, packages, integrated devices, integrated circuits, and/or transistors. In some instances, the figures may not be to scale. In some instances, for purpose of clarity, not all components and/or parts may be shown. In some instances, the position, the location, the sizes, and/or the shapes of various parts and/or components in the figures may be exemplary. In some implementations, various components and/or parts in the figures may be optional.

The word “exemplary” is used herein to mean “serving as an example, instance, or illustration.” Any implementation or aspect described herein as “exemplary” is not necessarily to be construed as preferred or advantageous over other aspects of the disclosure. Likewise, the term “aspects” does not require that all aspects of the disclosure include the discussed feature, advantage or mode of operation. The term “coupled” is used herein to refer to the direct or indirect coupling (e.g., mechanical coupling) between two objects. For example, if object A physically touches object B, and object B touches object C, then objects A and C may still be considered coupled to one another—even if they do not directly physically touch each other. An object A, that is coupled to an object B, may be coupled to at least part of object B. The term “electrically coupled” may mean that two objects are directly or indirectly coupled together such that an electrical current (e.g., signal, power, ground) may travel between the two objects. Two objects that are electrically coupled may or may not have an electrical current traveling between the two objects. The use of the terms “first”, “second”, “third” and “fourth” (and/or anything above fourth) is arbitrary. Any of the components described may be the first component, the second component, the third component or the fourth component. For example, a component that is referred to a second component, may be the first component, the second component, the third component or the fourth component. The terms “encapsulate”, “encapsulating” and/or any derivation means that the object may partially encapsulate or completely encapsulate another object. The terms “top” and “bottom” are arbitrary. A component that is located on top may be located over a component that is located on a bottom. A top component may be considered a bottom component, and vice versa. As described in the disclosure, a first component that is located “over” a second component may mean that the first component is located above or below the second component, depending on how a bottom or top is arbitrarily defined. In another example, a first component may be located over (e.g., above) a first surface of the second component, and a third component may be located over (e.g., below) a second surface of the second component, where the second surface is opposite to the first surface. It is further noted that the term “over” as used in the present application in the context of one component located over another component, may be used to mean a component that is on another component and/or in another component (e.g., on a surface of a component or embedded in a component). Thus, for example, a first component that is over the second component may mean that (1) the first component is over the second component, but not directly touching the second component, (2) the first component is on (e.g., on a surface of) the second component, and/or (3) the first component is in (e.g., embedded in) the second component. A first component that is located “in” a second component may be partially located in the second component or completely located in the second component. A value that is about X-XX, may mean a value that is between X and XX, inclusive of X and XX. The value(s) between X and XX may be discrete or continuous. The term “about ‘value X’”, or “approximately value X”, as used in the disclosure means within 10 percent of the ‘value X’. For example, a value of about 1 or approximately 1, would mean a value in a range of 0.9-1.1. A “plurality” of components may include all the possible components or only some of the components from all of the possible components. For example, if a device includes ten components, the use of the term “the plurality of components” may refer to all ten components or only some of the components from the ten components.

In some implementations, an interconnect is an element or component of a device or package that allows or facilitates an electrical connection between two points, elements and/or components. In some implementations, an interconnect may include a trace, a via, a pad, a pillar, a metallization layer, a redistribution layer, and/or an under bump metallization (UBM) layer/interconnect. In some implementations, an interconnect may include an electrically conductive material that may be configured to provide an electrical path for a signal (e.g., a data signal), ground and/or power. An interconnect may include more than one element or component. An interconnect may be defined by one or more interconnects. An interconnect may include one or more metal layers. An interconnect may be part of a circuit. Different implementations may use different processes and/or sequences for forming the interconnects. In some implementations, a chemical vapor deposition (CVD) process, a physical vapor deposition (PVD) process, a sputtering process, a spray coating, and/or a plating process may be used to form the interconnects.

Also, it is noted that various disclosures contained herein may be described as a process that is depicted as a flowchart, a flow diagram, a structure diagram, or a block diagram. Although a flowchart may describe the operations as a sequential process, many of the operations can be performed in parallel or concurrently. In addition, the order of the operations may be re-arranged. A process is terminated when its operations are completed.

In the following, further examples are described to facilitate the understanding of the disclosure.

According to Example 1, a device includes a substrate including: a set of metal layers, separated from one another by a set of dielectric layers, the set of metal layers defining a first set of metal lines and a second set of metal lines; a first set of conductive pillars configured to be electrically connected to a first die; a second set of conductive pillars interconnecting the first set of metal lines to the first set of conductive pillars; a first set of pads configured to be electrically connected to the first die; and a first set of conductive vias interconnecting the second set of metal lines to the first set of pads; wherein the first set of conductive pillars extend from a surface of the substrate.

Example 2 includes the device of Example 1, wherein a smallest distance between pillars of the first set of conductive pillars is smaller than a smallest distance between pads of the first set of pads.

Example 3 includes the device of Example 1 or Example 2, and further includes a second set of pads configured to electrically coupled to a second die; a third set of conductive pillars configured to be electrically connected to the second die; and a fourth set of conductive pillars interconnecting the first set of metal lines to the third set of conductive pillars to interconnect the first die to the second die.

Example 4 includes the device of any of Examples 1 to 3, wherein the first set of conductive pillars includes a first pillar and a second pillar that is adjacent to the first pillar, and wherein multiple metal lines of the first set of metal lines are between the first pillar and the second pillar.

Example 5 includes the device of any of Examples 1 to 4, wherein a first pitch of the first set of pads is greater than 90 micrometers, and wherein a second pitch of the first set of conductive pillars is less than 80 micrometers.

Example 6 includes the device of any of Examples 1 to 5, wherein the first set of pads have first characteristic dimensions and the first set of conductive pillars have second characteristic dimensions, and wherein the first characteristic dimensions are greater than the second characteristic dimensions.

Example 7 includes the device of any of Examples 1 to 6, wherein the second set of conductive pillars have a first characteristic horizontal dimension and the first set of conductive vias have a second characteristic horizontal dimension, and wherein the first characteristic horizontal dimension is smaller than the second characteristic horizontal dimension.

Example 8 includes the device of any of Examples 1 to 7, wherein a conductive pillar of the second set of conductive pillars includes a conductive material extending from a lower line formed at a lower metal layer to an upper line formed at an upper metal layer, wherein a dielectric layer is between the lower metal layer and the upper metal layer, and wherein an interface between the upper line and the conductive material is below an upper surface of the dielectric layer.

Example 9 includes the device of any of Examples 1 to 7, wherein a conductive pillar of the second set of conductive pillars includes a conductive material extending from a lower line formed at a lower metal layer to an upper line formed at an upper metal layer, wherein a dielectric layer is between the lower metal layer and the upper metal layer, and wherein a portion of the conductive material extends above an upper surface of the dielectric layer to form an interface with the upper line.

According to Example 10, a device includes a first die comprising first circuitry; a second die comprising second circuitry; and a substrate configured to electrically connect the first circuitry to the second circuitry and to electrically connect the first circuitry, the second circuitry, or both, to one or more off-package devices, the substrate includes a set of metal layers, separated from one another by a set of dielectric layers, the set of metal layers defining a first set of metal lines and a second set of metal lines; a first set of conductive pillars electrically connected to the first die; a first set of pads electrically connected to the first die; a second set of conductive pillars interconnecting the first set of metal lines to the first set of conductive pillars; a first set of conductive vias interconnecting the second set of metal lines to the first set of pads; a third set of conductive pillars electrically connected to the second die; a second set of pads electrically connected to the second die; a fourth set of conductive pillars interconnecting the first set of metal lines to the third set of conductive pillars to interconnect the first die to the second die; and a second set of conductive vias interconnecting the second set of metal lines to the second set of pads; wherein the first set of conductive pillars and the third set of conductive pillars extend from a surface of the substrate.

Example 11 includes the device of Example 10, wherein the first set of conductive pillars includes a first pillar and a second pillar that is adjacent to the first pillar, and wherein multiple metal lines of the first set of metal lines are between the first pillar and the second pillar.

Example 12 includes the device of Example 10 or Example 11, wherein the first set of pads have first characteristic dimensions and the first set of conductive pillars have second characteristic dimensions, and wherein the first characteristic dimensions are greater than the second characteristic dimensions.

Example 13 includes the device of any of Examples 10 to 12, wherein the second set of conductive pillars have a first characteristic horizontal dimension and the first set of conductive vias have a second characteristic horizontal dimension, and wherein the first characteristic horizontal dimension is smaller than the second characteristic horizontal dimension.

According to Example 14, a method of fabrication includes forming, in a metal layer of a substrate, first metal lines of a first set of metal lines and second metal lines of a second set of metal lines; forming, in a dielectric layer above the metal layer, second conductive pillars connected to the first metal lines; forming, in the dielectric layer, conductive vias connected to the second metal lines; forming pads connected to the conductive vias and configured to be electrically connected to a first die; and forming first conductive pillars connected to the second conductive pillars and configured to be electrically connected to the first die, wherein the first conductive pillars extend from a surface of the substrate.

Example 15 includes the method of Example 14, wherein forming the second conductive pillars includes: performing photoresist processing to form first holes in a photoresist layer above the metal layer; depositing conductive material of the second conductive pillars into the first holes; removing the photoresist layer to expose the conductive material; and laminating the dielectric layer over the exposed conductive material.

Example 16 includes the method of Example 14 or Example 15, and further includes mechanically thinning the dielectric layer and performing a soft etch to expose upper surfaces of the conductive material in recesses of an upper surface of the dielectric layer; and forming lines that contact the upper surfaces of the conductive material, wherein an interface between the lines and the conductive material is below the upper surface of the dielectric layer.

Example 17 includes the method of Example 14 or Example 15, and further includes performing a desmear process to expose upper portions of the conductive material by removing an epoxy layer from the dielectric layer; and forming lines that encapsulate the exposed upper portions of the conductive material, wherein the upper portions of the conductive material extend above an upper surface of the dielectric layer to form an interface with the lines.

Example 18 includes the method of any of Examples 14 to 17, wherein forming the second conductive vias includes: forming second holes in the dielectric layer using a laser drilling process; and depositing conductive material of the conductive vias into the second holes.

Example 19 includes the method of any of Examples 14 to 18, wherein the second conductive pillars have a smaller horizontal dimension than the conductive vias.

Example 20 includes the method of any of Examples 14 to 19, and further includes forming a solder resist layer on the dielectric layer; and forming openings in the solder resist layer using a laser drilling process to expose an upper surface of the pads, wherein the first conductive pillars protrude above an upper surface of the solder resist layer.

The various features of the disclosure described herein can be implemented in different systems without departing from the disclosure. It should be noted that the foregoing aspects of the disclosure are merely examples and are not to be construed as limiting the disclosure. The description of the aspects of the present disclosure is intended to be illustrative, and not to limit the scope of the claims. As such, the present teachings can be readily applied to other types of apparatuses and many alternatives, modifications, and variations will be apparent to those skilled in the art.

1. A device comprising:
a substrate including:
a set of metal layers, separated from one another by a set of dielectric layers, the set of metal layers defining a first set of metal lines and a second set of metal lines;
a first set of conductive pillars configured to be electrically connected to a first die;
a second set of conductive pillars interconnecting the first set of metal lines to the first set of conductive pillars;
a first set of pads configured to be electrically connected to the first die; and
a first set of conductive vias interconnecting the second set of metal lines to the first set of pads;
wherein the first set of conductive pillars extend from a surface of the substrate.

2. The device of claim 1, wherein a smallest distance between pillars of the first set of conductive pillars is smaller than a smallest distance between pads of the first set of pads.

3. The device of claim 1, further comprising:
a second set of pads configured to be electrically coupled to a second die;
a third set of conductive pillars configured to be electrically connected to the second die; and
a fourth set of conductive pillars interconnecting the first set of metal lines to the third set of conductive pillars to interconnect the first die to the second die.

4. The device of claim 1, wherein the first set of conductive pillars includes a first pillar and a second pillar that is adjacent to the first pillar, and wherein multiple metal lines of the first set of metal lines are between the first pillar and the second pillar.

5. The device of claim 1, wherein a first pitch of the first set of pads is greater than 90 micrometers, and wherein a second pitch of the first set of conductive pillars is less than 80 micrometers.

6. The device of claim 1, wherein the first set of pads have first characteristic dimensions and the first set of conductive pillars have second characteristic dimensions, and wherein the first characteristic dimensions are greater than the second characteristic dimensions.

7. The device of claim 1, wherein the second set of conductive pillars have a first characteristic horizontal dimension and the first set of conductive vias have a second characteristic horizontal dimension, and wherein the first characteristic horizontal dimension is smaller than the second characteristic horizontal dimension.

8. The device of claim 1, wherein a conductive pillar of the second set of conductive pillars includes a conductive material extending from a lower line formed at a lower metal layer to an upper line formed at an upper metal layer, wherein a dielectric layer is between the lower metal layer and the upper metal layer, and wherein an interface between the upper line and the conductive material is below an upper surface of the dielectric layer or is formed by a portion of the conductive material that extends above an upper surface of the dielectric layer

9. The device of claim 1, wherein the first die corresponds to a first chiplet and the second die corresponds to a second chiplet.

10. A device comprising:
a first die comprising first circuitry;
a second die comprising second circuitry; and
a substrate configured to electrically connect the first circuitry to the second circuitry and to electrically connect the first circuitry, the second circuitry, or both, to one or more off-package devices, the substrate comprising:
a set of metal layers, separated from one another by a set of dielectric layers, the set of metal layers defining a first set of metal lines and a second set of metal lines;
a first set of conductive pillars electrically connected to the first die;
a first set of pads electrically connected to the first die;
a second set of conductive pillars interconnecting the first set of metal lines to the first set of conductive pillars;
a first set of conductive vias interconnecting the second set of metal lines to the first set of pads;
a third set of conductive pillars electrically connected to the second die;
a second set of pads electrically connected to the second die;
a fourth set of conductive pillars interconnecting the first set of metal lines to the third set of conductive pillars to interconnect the first die to the second die; and
a second set of conductive vias interconnecting the second set of metal lines to the second set of pads;
wherein the first set of conductive pillars and the third set of conductive pillars extend from a surface of the substrate.

11. The device of claim 10, wherein the first set of conductive pillars includes a first pillar and a second pillar that is adjacent to the first pillar, and wherein multiple metal lines of the first set of metal lines are between the first pillar and the second pillar.

12. The device of claim 10, wherein the first set of pads have first characteristic dimensions and the first set of conductive pillars have second characteristic dimensions, and wherein the first characteristic dimensions are greater than the second characteristic dimensions.

13. The device of claim 10, wherein the first die corresponds to a first chiplet and the second die corresponds to a second chiplet.

14. A method of fabrication comprising:
forming, in a metal layer of a substrate, first metal lines of a first set of metal lines and second metal lines of a second set of metal lines;
forming, in a dielectric layer above the metal layer, second conductive pillars connected to the first metal lines;
forming, in the dielectric layer, conductive vias connected to the second metal lines;
forming pads connected to the conductive vias and configured to be electrically connected to a first die; and
forming first conductive pillars connected to the second conductive pillars and configured to be electrically connected to the first die,
wherein the first conductive pillars extend from a surface of the substrate.

15. The method of claim 14, wherein forming the second conductive pillars includes:
performing photoresist processing to form first holes in a photoresist layer above the metal layer;
depositing conductive material of the second conductive pillars into the first holes;
removing the photoresist layer to expose the conductive material; and
laminating the dielectric layer over the exposed conductive material.

16. The method of claim 15, further comprising:
mechanically thinning the dielectric layer and performing a soft etch to expose upper surfaces of the conductive material in recesses of an upper surface of the dielectric layer; and
forming lines that contact the upper surfaces of the conductive material,
wherein an interface between the lines and the conductive material is below the upper surface of the dielectric layer.

17. The method of claim 15, further comprising:
performing a desmear process to expose upper portions of the conductive material by removing an epoxy layer from the dielectric layer; and
forming lines that encapsulate the exposed upper portions of the conductive material,
wherein the upper portions of the conductive material extend above an upper surface of the dielectric layer to form an interface with the lines.

18. The method of claim 15, wherein forming the conductive vias includes:
forming second holes in the dielectric layer using a laser drilling process; and
depositing conductive material of the conductive vias into the second holes.

19. The method of claim 14, wherein the second conductive pillars have a smaller horizontal dimension than the conductive vias.

20. The method of claim 14, further comprising:
forming a solder resist layer on the dielectric layer; and
forming openings in the solder resist layer using a laser drilling process to expose an upper surface of the pads,
wherein the first conductive pillars protrude above an upper surface of the solder resist layer.
